(19) United States
(12) Patent Application Publication
(10) Pub. No.: US 2019/0081155 A1
(43) Pub. Date: Mar. 14, 2019

(54) NANOSHEET TRANSISTOR WITH IMPROVED INNER SPACER

(71) Applicant: GLOBALFOUNDRIES INC., GRAND CAYMAN (KY)

(72) Inventors: Ruilong XIE, Schenectady, NY (US); Kangguo CHENG, Schenectady, NY (US); Nicolas LOUBET, Guilderland, NY (US); Xin MIAO, Guilderland, NY (US); Pietro MONTANINI, Yorktown Heights, NY (US); John ZHANG, Alamont, NY (US); Haigou HUANG, Rexford, NY (US); Jianwei PENG, Latham, NY (US); Sipeng GU, Clifton Park, NY (US); Hui ZANG, Guilderland, NY (US); Yi QI, Niskayuna, NY (US); Xusheng WU, Ballston Lake, NY (US)

(73) Assignee: GLOBALFOUNDRIES INC., GRAND CAYMAN (KY)

(21) Appl. No.: 15/703,221

(22) Filed: Sep. 13, 2017

(51) Int. Cl. H01L 29/66; H01L 21/02; H01L 21/3065; H01L 29/06; H01L 29/423; H01L 29/786

(52) U.S. Cl. CPC H01L 29/66553; H01L 29/66772; H01L 29/66545; H01L 21/02532; H01L 21/02603; H01L 29/78618; H01L 29/0673; H01L 29/42392; H01L 29/78654; H01L 29/7869; H01L 21/3065

(57) ABSTRACT

A method of forming nanosheet and nanowire transistors includes the formation of alternating epitaxial layers of silicon germanium (SiGe) and silicon (Si), where the germanium content within respective layers of the silicon germanium is systemically varied in order to mediate the selective etching of these layers. The germanium content is controlled such that recessed regions created by partial removal of the silicon germanium layers have uniform lateral dimensions, and the backfilling of such recessed regions with an etch selective material results in the formation of a robust etch barrier.

### BACKGROUND

The present application relates generally to semiconductor devices, and more specifically to vertically-stacked nanosheet or nanowire transistors and their methods of production.

A nanosheet or a nanowire field effect transistor (FET) includes plural layers of nano-dimensional semiconductor material that function as the channel regions of the device. Such nanosheet- or nanowire-based structures enable feature scaling beyond current two-dimensional CMOS technology. However, conventional fabrication methods that use alternating sacrificial layers to offset the active nanostructures with respect to one another, as well as template their growth, may exhibit etch rate variability amongst the various sacrificial layers that can produce undesired variation in the lateral thickness of a protective inner spacer layer located between a sacrificial layer and an epitaxial source/drain junction. Such etch rate variation can result from geometric effects associated with patterning and etching a stack of layers.

Shown in FIG. 1, for example, is a schematic drawing of a comparative nanowire transistor at an intermediate stage of fabrication. The device includes a semiconductor substrate 10 with an array of alternately stacked layers 20, 30 formed thereon. The array of layers includes sacrificial silicon germanium (SiGe) layers 20 and active silicon (Si) layers 30. During subsequent fabrication, the sacrificial layers 20 of silicon germanium are removed and replaced with a gate all around (GAA) architecture that includes gate dielectric and gate conductor layers (not shown).

However, as will be appreciated, a step of laterally recessing the sacrificial silicon germanium layers 20 relative to the active silicon layers 30 may adversely influence the formation of robust inner spacers 50 located adjacent to the silicon germanium layers 20 and between overlying and underlying active silicon layers 30. In particular, referring to FIG. 2, an inner spacer 50 at each end of a recessed sacrificial silicon germanium layer 20 is adapted to function as an etch barrier that protects an adjacent epitaxial source/drain junction 60 during removal of remaining portions of the sacrificial silicon germanium layers 20 prior to the formation of the gate all around architecture. However, a non-uniform lateral etch rate of the sacrificial silicon germanium layers 20 during the recess etch results in a concave etch face, i.e., non-uniform etch profile, within the silicon germanium layers 20 and, upon filling the space created by the recess etch, a non-uniform lateral thickness (d) of an inner spacer layer 50 between the sacrificial silicon germanium layer 20 and the source/drain junction 60. In various approaches, the lateral thickness (d) of the inner spacer 50 immediately adjacent to an overlying or underlying layer of silicon 30 may be insufficient to provide an effective etch barrier.

After formation of the source/drain junctions 60, a further etching step is used to remove remaining portions of the sacrificial silicon germanium layer 20. During such an etch, the etch chemistry can circumvent thinner regions of the inner spacer 50, i.e., through region 22 between inner spacer 50 and silicon layer 30, and undesirably etch the source/drain junction 60 producing unwanted voids 61, for example.

### SUMMARY

Disclosed is a method for forming a nanosheet or nanowire FET having an improved inner spacer geometry. As disclosed herein, lateral etch back of the sacrificial SiGe layers and the attendant realization of an inner spacer having a smaller gradient across its lateral thickness may be achieved by offsetting the etch effects that contribute to a non-uniform etch profile with intra-layer variations in composition. Thus, various embodiments contemplate the use of composition, i.e., a compositionally graded silicon germanium layer, to control the etch rate within individual ones of various sacrificial layers.

For instance, an exemplary method of fabricating a device includes forming a stack of alternating layers of epitaxial silicon germanium and epitaxial silicon over a semiconductor substrate, forming a sacrificial gate structure over the stack, and etching the stack using the sacrificial gate structure as a mask to form a fin structure. The various silicon germanium layers each have a compositional gradient, where the germanium content within lower and upper regions of each layer is greater than the germanium content within an intermediate region between respective lower and upper regions.

The germanium content can vary continuously or in a step-wise manner. Thus, in various embodiments, within a layer of silicon germanium, upper and lower sub-layers, i.e., immediately adjacent to respective overlying and underlying layers of silicon, have a germanium content that is greater than the germanium content of an intermediate sub-layer that is located between the upper and lower sub-layers.

Further methods for fabricating a device include forming a stack of alternating layers of epitaxial silicon germanium and epitaxial silicon over a semiconductor substrate, such that forming each layer of silicon germanium includes forming a first sub-layer having a first germanium content, forming a second sub-layer over the first sub-layer having a second germanium content less than the first germanium content, and forming a third sub-layer over the second sub-layer having a third germanium content greater than the second germanium content.

A sacrificial gate structure is formed over the stack of alternating layers and sidewall spacers are formed over sidewalls of the sacrificial gate structure. Portions of the silicon germanium layers are removed from under the sidewall spacers to form recessed regions, wherein remaining portions of the silicon germanium layers each have a substantially constant width. The recessed regions are filled with an inner spacer material that provides improved shielding of the source/drain junctions during removal of the sacrificial layers.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a cross-sectional schematic illustration of a comparative nanosheet FET;

FIG. 2 is a cross-sectional schematic view of a comparative nanosheet FET having a laterally recessed sacrificial silicon germanium layer and laterally non-homogeneous inner spacer layers located between the silicon germanium layer and adjacent source/drain junctions;

FIG. 3 is a schematic view showing a compositionally graded sacrificial silicon germanium layer according to certain embodiments;

FIG. 4 is a schematic plot of germanium concentration as a function of thickness for the exemplary silicon germanium layer of FIG. 3;

FIG. 5 is a schematic view showing a compositionally graded sacrificial silicon germanium layer according to further embodiments;

FIG. 6 is a schematic plot of germanium concentration as a function of thickness for the exemplary silicon germanium layer of FIG. 5;

FIG. 7 is a cross-sectional schematic view of a laterally recessed sacrificial silicon germanium layer and exemplary inner spacer layers located between the silicon germanium layer and adjacent source/drain junctions;

FIG. 8 is a cross-sectional schematic view of a laterally recessed sacrificial silicon germanium layer and exemplary inner spacer layers located between the silicon germanium layer and adjacent source/drain junctions according to further embodiments;

FIG. 9 is a cross-sectional schematic view of a structure showing the formation of sacrificial gate structures over a stack comprising alternating epitaxial layers of compositionally-graded silicon germanium, and silicon according to various embodiments;

FIG. 10 depicts the formation of sidewall spacers over the sacrificial gate structures of FIG. 9;

FIG. 11 shows a self-aligned source/drain recess etch of the epitaxial layers adjacent to the sacrificial gate structures;

FIG. 12 depicts a lateral recess etch of the silicon germanium epitaxial layers according to various embodiments;

FIG. 13 depicts extension doping of the silicon layers outside of the channel regions thereof;

FIG. 14 shows the structure of FIG. 13 following inner spacer deposition between the doped layers of silicon;

FIG. 15 depicts the formation of epitaxial source/drain junctions;

FIG. 16 is a post-planarization structure after formation of an interlayer dielectric over the epitaxial source/drain regions and between the sacrificial gate structures;

FIG. 17 shows removal of the sacrificial gate structures;

FIG. 18 depicts selective removal of the silicon germanium epitaxial layers to expose the channel regions of the silicon layers; and

FIG. 19 shows the formation of a gate all around (GAA) gate architecture over the exposed channel regions.

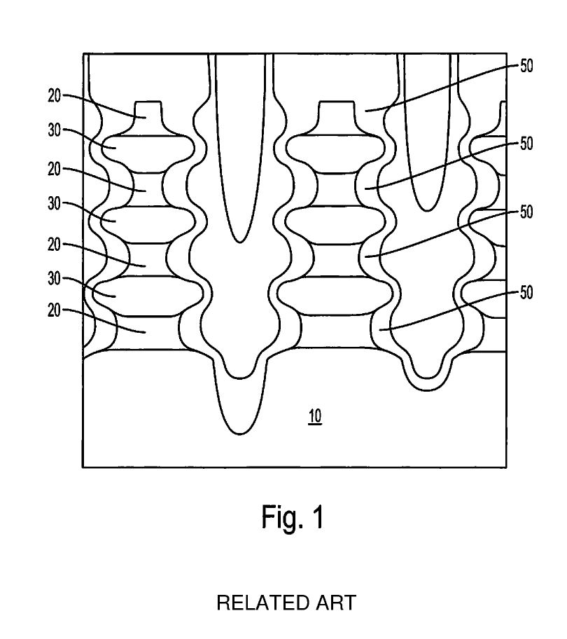

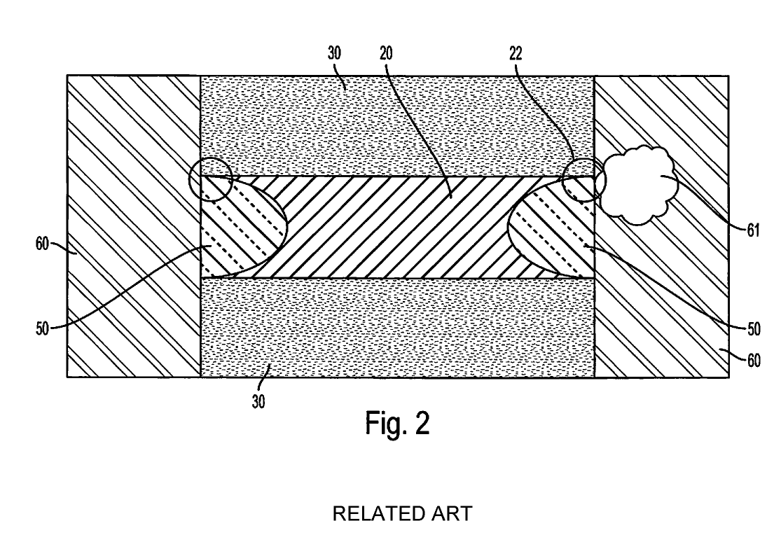

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

Disclosed are methods for forming a nanosheet or nanowire field effect transistor as well as a resulting nanostructure device. Gate all around (GAA) nanostructure channel transistors such as nanosheet and nanowire FETs enable feature scaling beyond current two-dimensional CMOS technology. Such devices include source and drain regions, and stacked nanostructured channel regions disposed therebetween. A gate, including a gate dielectric and a gate conductor, surrounds the stacked nano-dimensional channels and controls electron flow through the channels between the source and drain regions.

Nanosheet and nanowire devices can be formed from alternating epitaxial layers of an active semiconductor material such as silicon (Si) using sacrificial semiconductor material layers such as silicon germanium (SiGe) layers as templates for epitaxial growth and as inter-layer spacers. However, the three-dimensional geometry associated with multiple layers of disparate composition can challenge achieving a uniform removal rate of the sacrificial layers, which may lead to inconsistent inner spacer geometries.

Accordingly, the present disclosure provides fabrication methodologies and resulting devices for stacked nanosheet and nanowire transistors having improved inner spacer lateral thickness throughout a device comprising plural active layers.

As used herein, a “nanowire” device is characterized by a channel having a critical dimension (CD) of less than 30 nm, while a “nanosheet” device is characterized by a channel having a critical dimension of 30 nm or greater. In exemplary devices, the critical dimension is measured along the gate. In that direction, if the width of the GAA channel is small, the channel cross-section is like a “wire” whereas if the width of the GAA channel is large, the channel cross-section is like a “sheet.” As will be appreciated, the presently disclosed methods may be incorporated into the manufacture of nanosheet as well as nanowire devices.

In one or more embodiments, the device fabrication methodology includes processes and materials that counteract geometrically-driven variability in the etch profile of the sacrificial layers, which can result in a more uniform inner spacer lateral dimension. Such inner spacers provide effective etch barriers. In several embodiments, the composition of the SiGe layers used as sacrificial layers is systematically controlled in order to tailor the etch rate of each SiGe layer, which can be used to offset the local geometric etch effects.

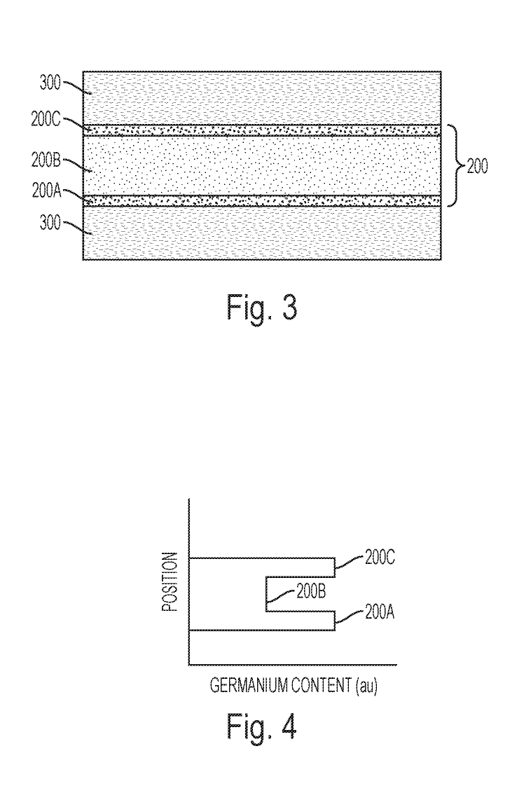

According to various embodiments, the sacrificial silicon germanium (SiGeₓ) layers include a bi-directional composition gradient. Referring to FIG. 3, for example, a compositionally graded silicon germanium layer 200 may be formed as a composite of discrete, compositionally-distinct sub-layers 200A, 200B, 200C. Such an epitaxial silicon germanium layer 200 may have an abrupt, step-change in germanium content as a function of layer thickness, where the layer 200 has a higher germanium content within lower and upper sub-layers 200A, 200C that are immediately adjacent to underlying and overlying silicon layers 300, and a lower germanium content within an intermediate sub-layer 200B. A schematic of the corresponding germanium profile is shown in FIG. 4.

The germanium content within each sub-layer 200A, 200B, 200C may independently vary from 5 to 70 atomic percent, e.g., 5, 10, 15, 20, 25, 30, 35, 40, 45, 50, 55, 60, 65 or 70%, including ranges between any of the foregoing values. In certain embodiments, the germanium content within the intermediate sub-layer 200B is at least 5 at. % less than the germanium content in either or both of the lower and upper sub-layers 200A, 200C. A difference in the germanium content between an intermediate sub-layer 200B and one or both of the lower and upper sub-layers 200A, 200C may be 5, 10, 15, 20, 25, 30 or 35 atomic percent, including ranges between any of the foregoing values.

By way of example, a compositionally graded silicon germanium layer 200 may include first and third sub-layers 200A, 200C each comprising 45 at. % Ge, and an intermediate sub-layer 200B comprising 25 at. % Ge. In a further example, first and third sub-layers 200A, 200C may each comprise 20 at. % Ge, and intermediate sub-layer 200B may comprise 15 at. % Ge.

A total thickness of the sacrificial silicon germanium layer 200 may range from 5 to 30 nm, e.g., 5, 10, 15, 20 25 or 30 nm, including ranges between any of the foregoing values. The thickness of each sub-layer 200A, 200B, 200C may independently range from 1 to 28 nm, e.g., 1, 2, 3, 4, 5, 10, 12, 15, 20, 25 or 28 nm, including ranges between any of the foregoing values. For example, a compositionally graded silicon germanium layer 200 may include first and third sub-layers 200A, 200C each having a thickness of 1 nm and each comprising 45 at. % Ge, and an intermediate second sub-layer 200B between the first and third sub-layers having a thickness of 8 nm and comprising 25 at. % Ge. In a further example, first and third sub-layers 200A, 200C may each have a thickness of 2 nm and each comprise 20 at. % Ge, and intermediate second sub-layer 200B may have a thickness of 10 nm and comprise 15 at. % Ge. As shown, the germanium composition within each sub-layer may be constant.

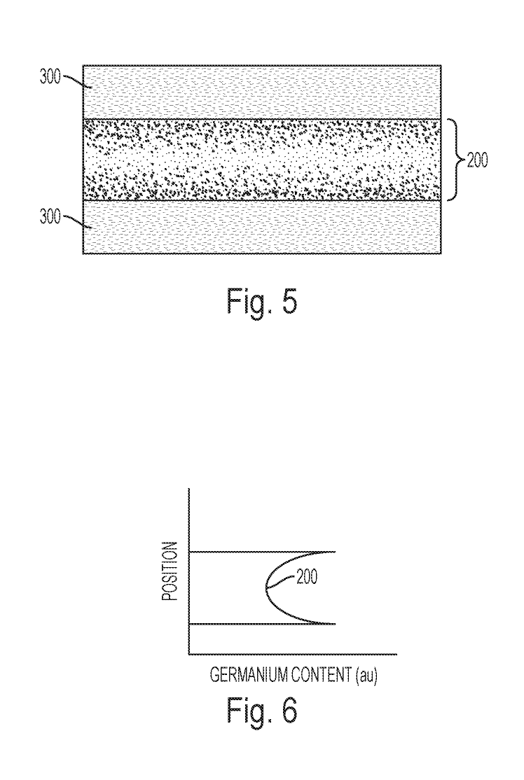

In alternate embodiments, the germanium composition within each sub-layer may vary, e.g., linearly, from a maximum value at the upper and lower surfaces to a minimum value there-between. In further embodiments, the composition of the sacrificial silicon germanium layer 200 may vary continuously from its lower surface to its upper surface, where the germanium content is greatest at the lower and upper surfaces. A schematic of an exemplary sacrificial silicon germanium layer 200 having a continuous, bi-directional germanium gradient is shown in FIG. 5, and a corresponding plot of the germanium content as a function of layer thickness is shown in FIG. 6. As in the previous embodiment, a local germanium content within the silicon germanium layer 200 may range from 5 to 70 atomic percent, e.g., 5, 10, 15, 20, 25, 30, 35, 40, 45, 50, 55, 60, 65 or 70%, including ranges between any of the foregoing values.

By locally varying the germanium content within each silicon germanium layer, a substantially uniform lateral etch of the alternating silicon germanium layers can be achieved, resulting in an inner spacer having a substantially constant width (d) throughout its thickness. As used herein, a “substantially constant” width (d) varies by 20% or less, e.g., 0, 2, 5, 10 or 20%, including ranges between any of the foregoing values.

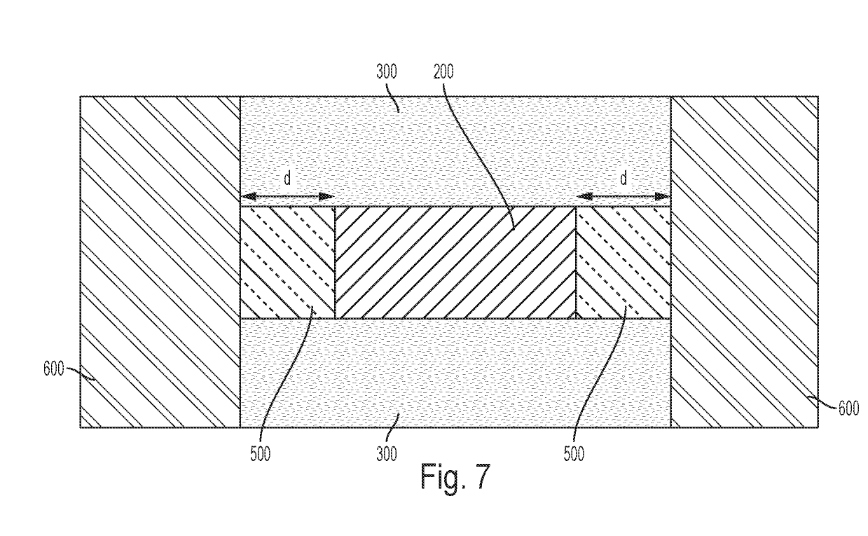

Referring to FIG. 7, shown is a cross-sectional schematic view of a laterally-recessed sacrificial silicon germanium layer 200 and exemplary inner spacer layers 500 located between the silicon germanium layer 200 and adjacent source/drain junctions 600. The inner spacer layers 500, which are disposed between overlying and underlying silicon layers 300, have a substantially constant lateral width (d).

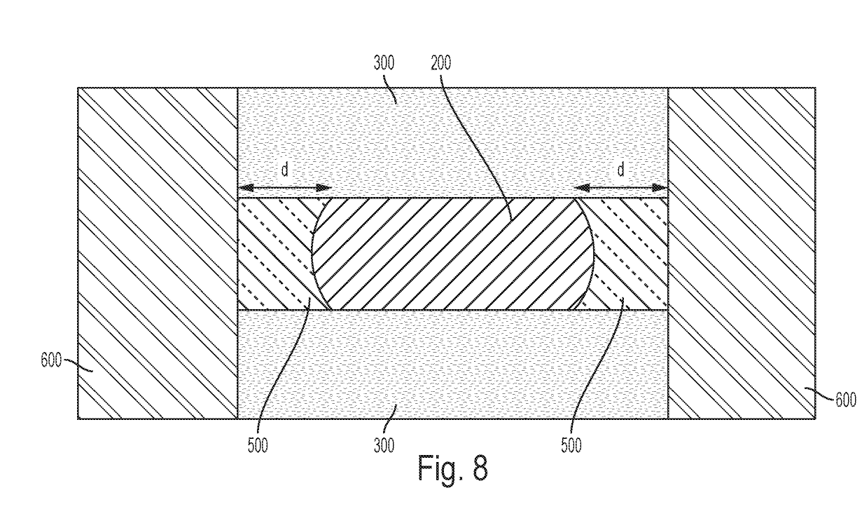

FIG. 8 is a cross-sectional schematic view of a laterally recessed sacrificial silicon germanium layer 200 and exemplary inner spacer layers 500 according to further embodiments. Inner spacer layers 500 are located between the silicon germanium layer 200 and adjacent source/drain junctions 600, and each have a substantially constant lateral width (d). In the illustrated embodiment, remaining portions of the silicon germanium layer 200 have a convex etch face, such that upper and lower portions of the inner spacer layers 500 have a lateral width that is greater than or equal to a lateral width of an intermediate portion between the upper and lower portions.

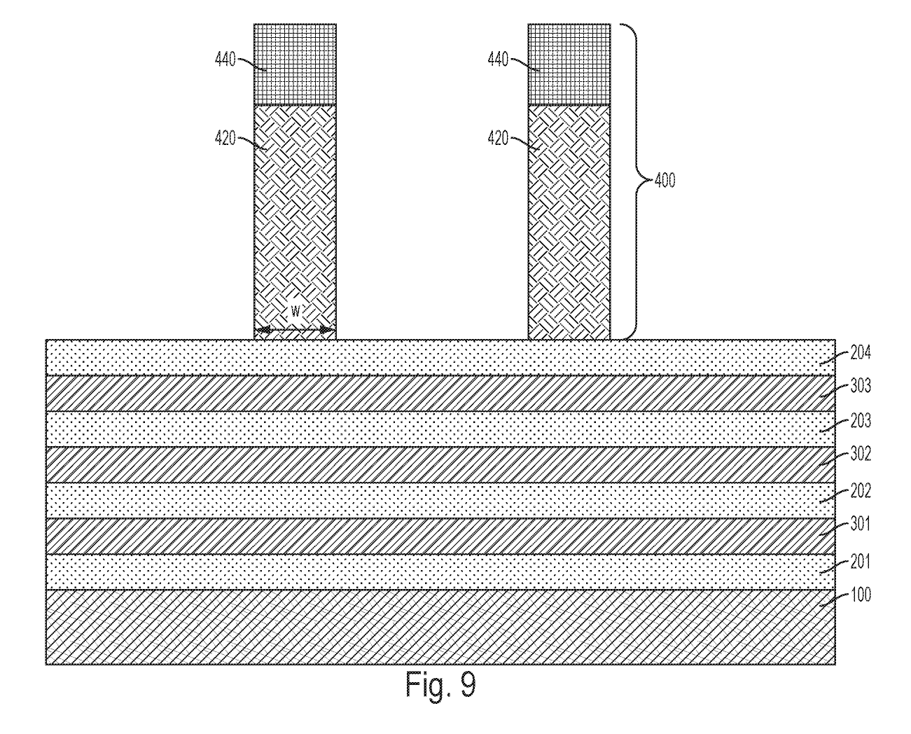

An exemplary process flow for forming a nanowire or nanosheet device is described herein with reference to FIGS. 9-19. As shown in FIG. 9, sacrificial epitaxial layers 201, 202, 203, 204 and semiconductor epitaxial layers 301, 302, 303 are alternately formed as a stack over a substrate 100.

The substrate 100 may include a semiconductor material such as silicon, e.g., single crystal Si or polycrystalline Si, or a silicon-containing material. Silicon-containing materials include, but are not limited to, single crystal silicon germanium (SiGe), polycrystalline silicon germanium, silicon doped with carbon (Si:C), amorphous Si, as well as combinations and multi-layers thereof. As used herein, the term “single crystal” denotes a crystalline solid, in which the crystal lattice of the entire solid is substantially continuous and substantially unbroken to the edges of the solid with substantially no grain boundaries.

The substrate 100 is not limited to silicon-containing materials, however, as the substrate 100 may comprise other semiconductor materials, including Ge and compound semiconductors, including III-V compound semiconductors such as GaAs, InAs, GaN, GaP, InSb, ZnSe, and ZnS, and II-VI compound semiconductors such as CdSe, CdS, CdTe, ZnSe, ZnS and ZnTe.

Substrate 100 may be a bulk substrate or a composite substrate such as a semiconductor-on-insulator (SOI) substrate that comprises, from bottom to top, a handle portion, an isolation layer (e.g., buried oxide layer), and a semiconductor material layer.

Substrate 100 may have dimensions as typically used in the art and may comprise, for example, a semiconductor wafer. Example wafer diameters include, but are not limited to, 50, 100, 150, 200, 300 and 450 mm. The total substrate thickness may range from 250 microns to 1500 microns, although in particular embodiments the substrate thickness is in the range of 725 to 775 microns, which corresponds to thickness dimensions commonly used in silicon CMOS processing. The semiconductor substrate 100 may comprise (100)-oriented silicon or (111)-oriented silicon, for example. In example embodiments, the as-deposited semiconductor layers are undoped.

In various embodiments, the stack of epitaxial layers is configured such that a first sacrificial layer 201 is formed directly over the substrate 100, followed by alternating semiconductor and sacrificial layers. In various embodiments, the epitaxial stack terminates with a sacrificial layer, such that each semiconductor layer 300 is sandwiched between an underlying and an overlying sacrificial layer. For simplicity of illustration, four sacrificial layers 200 (201, 202, 203, 204) and three semiconductor layers 300 (301, 302, 303) are shown. However, fewer or greater sacrificial layers and/or semiconductor layers may for formed by epitaxial growth in an alternating fashion over substrate 100.

The terms “epitaxy,” “epitaxial” and/or “epitaxial growth and/or deposition” refer to the formation of a semiconductor material layer on a deposition surface of a semiconductor material, in which the semiconductor material layer being grown assumes the same crystalline habit as the semiconductor material of the deposition surface. For example, in an epitaxial deposition process, chemical reactants provided by source gases are controlled and the system parameters are set so that depositing atoms alight on the deposition surface and remain sufficiently mobile via surface diffusion to orient themselves according to the crystalline orientation of the atoms of the deposition surface. Therefore, an epitaxial semiconductor material will adopt the same crystalline characteristics as the deposition surface on which it is formed. For example, an epitaxial semiconductor material deposited on a (100) crystal surface will take on a (100) orientation.

In the instant method, sacrificial layers 200 serve as spacer layers that offset the semiconductor layers 300 from each other. The sacrificial layers 200 also serve as template layers upon which the semiconductor layers can be grown epitaxially.

Epitaxial layers (i.e., the sacrificial layers and the semiconductor layers) may be formed by a reduced pressure molecular beam epitaxy (MBE) or a chemical vapor deposition (CVD) process, for example, at a substrate temperature of 450-700° C. and a growth pressure (i.e., chamber pressure) of 0.1-700 Torr. A source of silicon may include silane gas (SiH₄), and a germanium source for the SiGeₓ epitaxy may include germane gas (GeH₄). Hydrogen may be used as a carrier gas.

According to various embodiments, a first silicon germanium (SiGeₓ) layer 201 is epitaxially grown on a semiconductor substrate 100. During an exemplary process, a silicon precursor (e.g., silane) flows concurrently into a process chamber with a carrier gas (e.g., H₂ and/or N₂) and a germanium source (e.g., GeH₄ or GeCl₄). By way of example, the flow rate of the silicon source may be in the range of 5 sccm to 500 sccm, the flow rate of the germanium source may be in the range of 0.1 sccm to 10 sccm, and the flow rate of the carrier gas may be in the range of 1,000 sccm to 60,000 sccm, although lesser and greater flow rates may be used.

As will be appreciated, other suitable gas sources for silicon include silicon tetrachloride (SiCl₄), dichlorosilane (SiH₂Cl₂), trichlorosilane (SiHCl₃), and other hydrogen-reduced chlorosilanes (SiHₓCl₄₋ₓ). In lieu of germane, other germanium sources or precursors may be used to form epitaxial silicon germanium layers. Higher germanes include the compounds with the empirical formula GeₓH₍₂ₓ₊₂₎, such as digermane (Ge₂H₆), trigermane (Ge₃H₈) and tetragermane (Ge₄H₁₀), as well as others. Organogermanes include compounds with the empirical formula R_{y}GeₓH_{(2x+2-y)}, where R=methyl, ethyl, propyl or butyl, such as methylgermane ((CH₃)GeH₃), dimethylgermane ((CH₃)₂GeH₂), ethylgermane ((CH₃CH₂)GeH₃), methyldigermane ((CH₃)Ge₂H₅), dimethyldigermane ((CH₃)₂Ge₂H₄) and hexamethyldigermane ((CH₃)₆Ge₂).

The process chamber may be maintained at a pressure of 0.1 Torr to 700 Torr, while the substrate 100 is maintained at a temperature in the range of 450° C. to 700° C. The process according to certain embodiments is conducted to form an initial SiGe layer 201 with a thickness in a range of 5 to 30 nm. During the formation of each silicon germanium layer 200, the flow rate and/or the partial pressure of the silicon source and the germanium source can be varied to form SiGe layers having a bi-directional germanium gradient as described above.

Following deposition of the first silicon germanium layer 201, a first epitaxial silicon layer 301 is formed directly over the first silicon germanium layer 201. According to an example method, during deposition of the first silicon layer 301, a silicon precursor (e.g., silane) is flown concurrently into the process chamber with a carrier gas (e.g., H₂ and/or N₂). The flow rate of the silane may be in the range of 5 sccm to 500 sccm, and the flow rate of the carrier gas may be in the range of 1,000 sccm to 60,000 sccm, although lesser and greater flow rates may be used.

The process chamber for deposition of the silicon layer 301 may be maintained at a pressure of 0.1 Torr to 700 Torr, while the substrate 100 is maintained at a temperature in the range of 450° C. to 700° C. The process according to certain embodiments is conducted to form a first silicon layer 301 with a thickness in a range from 5 to 30 nm.

Following deposition of the first epitaxial silicon layer 301, according to the illustrated embodiment, alternating silicon germanium and silicon process conditions are used to successively deposit a second epitaxial silicon germanium layer 202 directly over the first epitaxial silicon layer 301, a second epitaxial silicon layer 302 directly over the second epitaxial silicon germanium layer 202, a third epitaxial silicon germanium layer 203 directly over the second epitaxial silicon layer 302, a third epitaxial silicon layer 303 directly over the third epitaxial silicon germanium layer 203, and a fourth epitaxial silicon germanium layer 204 directly over the third epitaxial silicon layer 303.

The process materials and conditions used to form the second, third and fourth silicon germanium layers 202, 203, 204 may be the same process materials and conditions used to form the first silicon germanium layer 201. The process materials and conditions used to form the second and third silicon layers 302, 303 may be the same process materials and conditions used to form the first silicon layer 301. In embodiments, one or more of the silicon germanium layers 201, 202, 203, 204 has a graded germanium content. For instance, each of the silicon germanium layers can have a graded germanium content.

In various methods, the formation of SiGe epitaxial layers having such an intralayer compositional gradient may be achieved by maintaining a constant partial pressure (e.g., flow rate) of the silicon precursor during each SiGe process, while decreasing or increasing the partial pressure (e.g., flow rate) of the germanium precursor. In alternate methods, the formation of the SiGe epitaxial layers may be achieved by maintaining a constant partial pressure (e.g., flow rate) of the germanium precursor during each SiGe process, while increasing or decreasing the partial pressure (e.g., flow rate) of the silicon precursor.

Thus, in various embodiments, the composition of the semiconductor layers 301, 302, 303, etc. may be constant over the stack, whereas the composition of the sacrificial layers 201, 202, 203, 204, etc. varies such that the germanium content within the upper and lower regions of each SiGe layer is greater than the germanium content within an intermediate region between the upper and lower regions.

In various embodiments, the thickness amongst the respective sacrificial SiGe layers 200 and amongst the semiconductor layers 300 may be constant, while the sacrificial SiGe layers 200 are thinner than the semiconductor layers. In alternate embodiments, the thickness amongst the respective sacrificial SiGe layers 200 and amongst the semiconductor layers 300 may be constant, while the sacrificial SiGe layers 200 are thicker than the semiconductor layers 300.

Referring still to FIGS. 9, a sacrificial gate structure 400 comprising a sacrificial gate layer 420 and a sacrificial gate cap 440 is formed over the substrate 100, i.e., directly over the stack of epitaxial layers, using patterning and etching processes known to those skilled in the art. The sacrificial gate layer 420 may comprise a layer of silicon dioxide and an overlying layer of amorphous silicon (a-Si), for example, and the sacrificial gate cap 440 may comprise silicon nitride. Amorphous elemental silicon can be deposited using chemical vapor deposition, such as low pressure chemical vapor deposition (LPCVD) at temperatures ranging from 450° C. to 700° C. Silane (SiH₄) can be used as the precursor for CVD silicon deposition.

Sacrificial gate structures 400 may be defined by a patterning process such as photolithography, for example, which includes forming a layer of photoresist material (not shown) atop one or more layers to be patterned. The photoresist material may include a positive-tone photoresist composition, a negative-tone photoresist composition, or a hybrid-tone photoresist composition. A layer of photoresist material may be formed by a deposition process such as, for example, spin-on coating.

The deposited photoresist is then subjected to a pattern of irradiation, and the exposed photoresist material is developed utilizing a conventional resist developer. The pattern provided by the patterned photoresist material is thereafter transferred into the sacrificial gate cap layer 440 and the sacrificial gate layer 420 utilizing at least one pattern transfer etching process.

The pattern transfer etching process is typically an anisotropic etch. In certain embodiments, a dry etching process such as, for example, reactive ion etching (RIE) can be used. In other embodiments, a wet chemical etchant can be used. In still further embodiments, a combination of dry etching and wet etching can be used.

The sacrificial gate layer 420 may be patterned to a width (w) of 15 to 25 nm and have a height of 50 to 200 nm, e.g., 50, 75, 100, 125, 150, 175 or 200 nm, including ranges between any of the foregoing values, although lesser and greater widths and thicknesses may be used. As appreciated by those skilled in the art, a shallow trench isolation layer (not shown) may provide electrical isolation between adjacent fin structures.

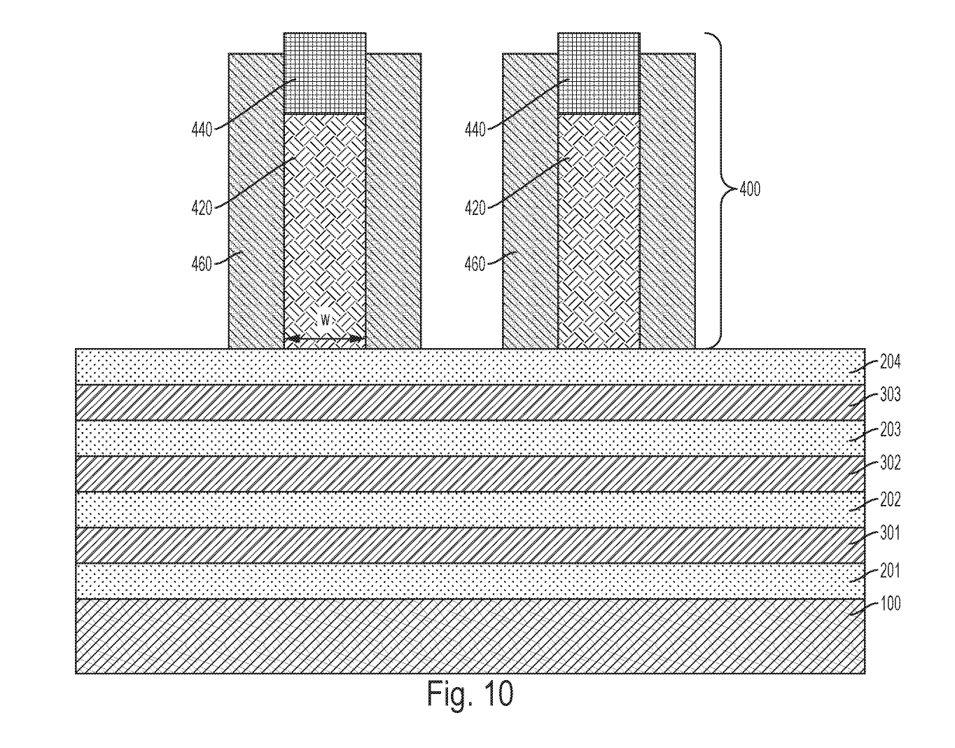

Referring to FIG. 10, sidewalls spacers 460 are formed over sidewalls (vertical surfaces) of the sacrificial gate structures 400. Sidewall spacers 460 may be formed by blanket (conformal) deposition of a spacer material (e.g., using an atomic layer deposition process), followed by a directional etch such as reactive ion etching (RIE) to remove the spacer material from horizontal surfaces. In certain embodiments, the sidewall spacer thickness is 5 to 20 nm, e.g., 5, 10, 15 or 20 nm, including ranges between any of the foregoing values.

Suitable sidewall spacer materials include oxides, nitrides and oxynitrides, such as silicon dioxide, silicon nitride, silicon oxynitride, and low dielectric constant (low-k) materials such as amorphous carbon, SiOC, SiOCN and SiBCN, as well as a low-k dielectric material. As used herein, a low-k material has a dielectric constant less than that of silicon dioxide.

Exemplary low-k materials include but are not limited to, amorphous carbon, fluorine-doped oxides, or carbon-doped oxides. Commercially-available low-k dielectric products and materials include Dow Corning's SiLK™ and porous SiLK™, Applied Materials' Black Diamond™, Texas Instrument's Coral™ and TSMC's Black Diamond™ and Coral™.

In various embodiments, the sidewall spacers 460 and the sacrificial gate 420 are formed from materials that can be etched selectively to one another. In particular embodiments, the sacrificial gate 420 comprises amorphous silicon (a-Si) and the sidewall spacers 460 comprises silicon nitride or SiOCN.

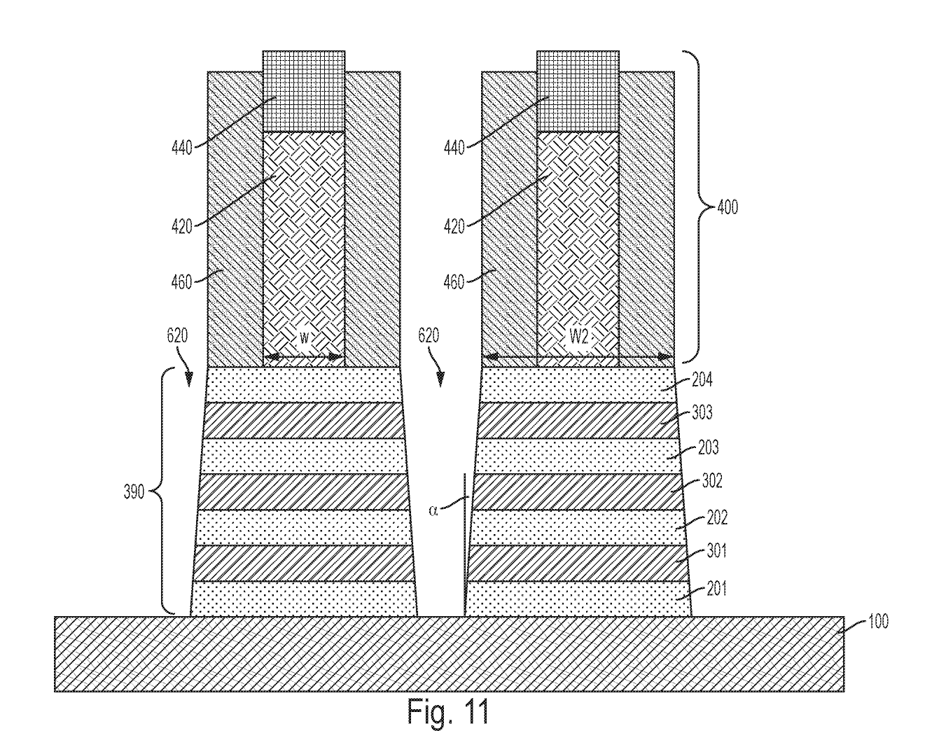

Referring to FIG. 11, using the sacrificial gate 400 and sidewall spacers 460 as an etch mask, exposed portions of the epitaxial layers are etched to create source/drain recesses 620 laterally adjacent to the sacrificial gate 400 and define composite fin structures 390. The etching may comprise a silicon RIE process, for example. As described in greater detail herein below, portions of the remaining stack defined by nanoscale silicon layers 301, 302, 303, once released from the sacrificial SiGe layers 201, 202, 203, 204, will form channels of a nanosheet or nanowire FET.

The fin structures 390 may have a width of 6 to 100 nm, e.g., 6, 10, 20, 50, 75 or 100 nm measured orthogonal to the gate width (w), and a width (W2) of 25 to 65 nm, e.g., 25, 30, 35, 40, 45, 50, 55, 60 or 65 nm, including ranges between any of the respective foregoing values, measured parallel to the gate width (w).

A fin structure having a width measured orthogonal to the gate width (w) that is less than 30 nm may be used to form a nanowire device, whereas a fin structure having a width measured orthogonal to the gate width (w) that is 30 nm or greater may be used to form a nanosheet device. In such devices, current will flow from a source region to a drain region through a channel region in a direction parallel to the gate width (w).

In various embodiments, as explained further below, sidewalls of the resulting fin structures 390 may deviate due to imperfection from vertical (i.e., deviate from a direction orthogonal to a major surface of the substrate) by a taper angle (α), where 0≤α≤15°.

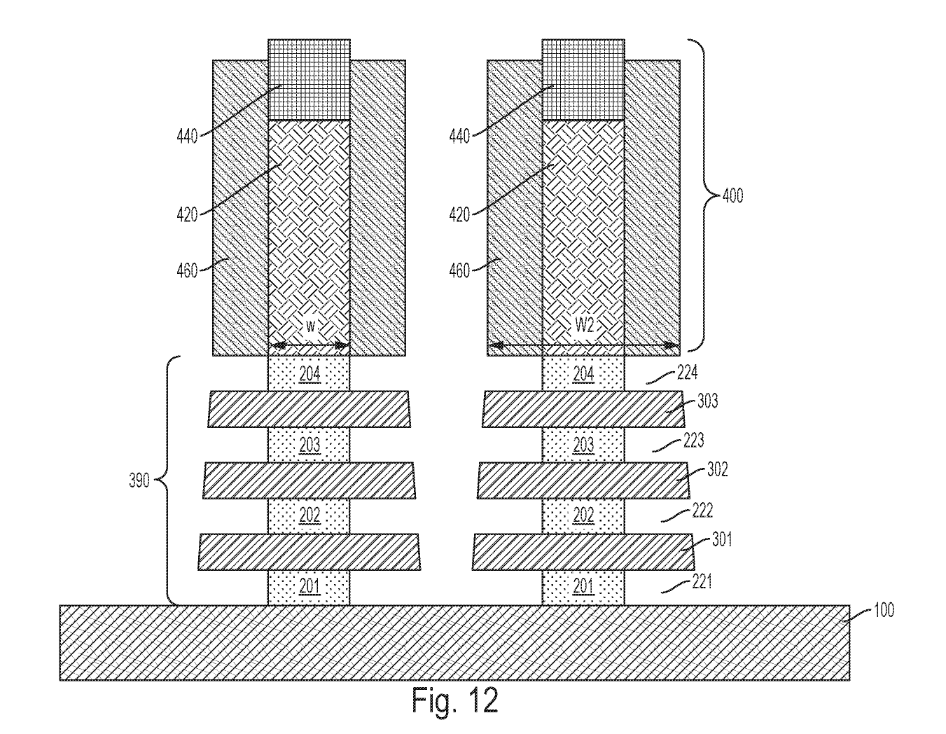

Then, referring to FIG. 12, sacrificial layers 201, 202, 203, 204 are recessed laterally beneath the sidewall spacers 460 using a selective isotropic etch, such as a hydrogen chloride (HCl)-based wet etch or a wet mixture comprising acetic acid (CH₃COOH), hydrogen peroxide (H₂O₂) and hydrofluoric acid (HF), to form corresponding recessed regions 221, 222, 223, 224. The selective etch removes SiGe, for example, without etching silicon. As illustrated, the recess etch may result in remaining portions of the sacrificial layers 201, 202, 203, 204 having a substantially constant width, which may be equal to the width (w) of the sacrificial gate layer 420. In alternate embodiments, a width of the remaining portions of the sacrificial layers 201, 202, 203, 204 may be less than or greater than the width (w) of the sacrificial gate layer 420. As will be appreciated, the starting widths of respective ones of the sacrificial layers 201, 202, 203, 203 may be unequal due to the taper associated with the etch of the fin structure described with reference to FIG. 11. The aspect ratio of the fin structures 390 and the overlying sacrificial gate structure 400 together with a relatively narrow spacing between adjacent sidewall spacers 460 may contribute to the tapered profile of the SiGe layers.

However, as disclosed herein, the variation in composition amongst respective ones of the sacrificial layers 201, 202, 203, 204 can be used to offset the geometric or shadowing effects to produce sacrificial layers 201, 202, 203, 204 having a substantially constant width following the recess etch. As used herein, “substantially equal” or “substantially constant” dimensions vary by less than 5%, e.g., 0, 1, 2, 3, 4 or 5%, including ranges between any of the foregoing values. In various embodiments, the relative etch rate (R) during the recess etch of the sacrificial layers 201, 202, 203, 204 may be characterized as R(200A)>R(200B) and R(200C)>R(200B).

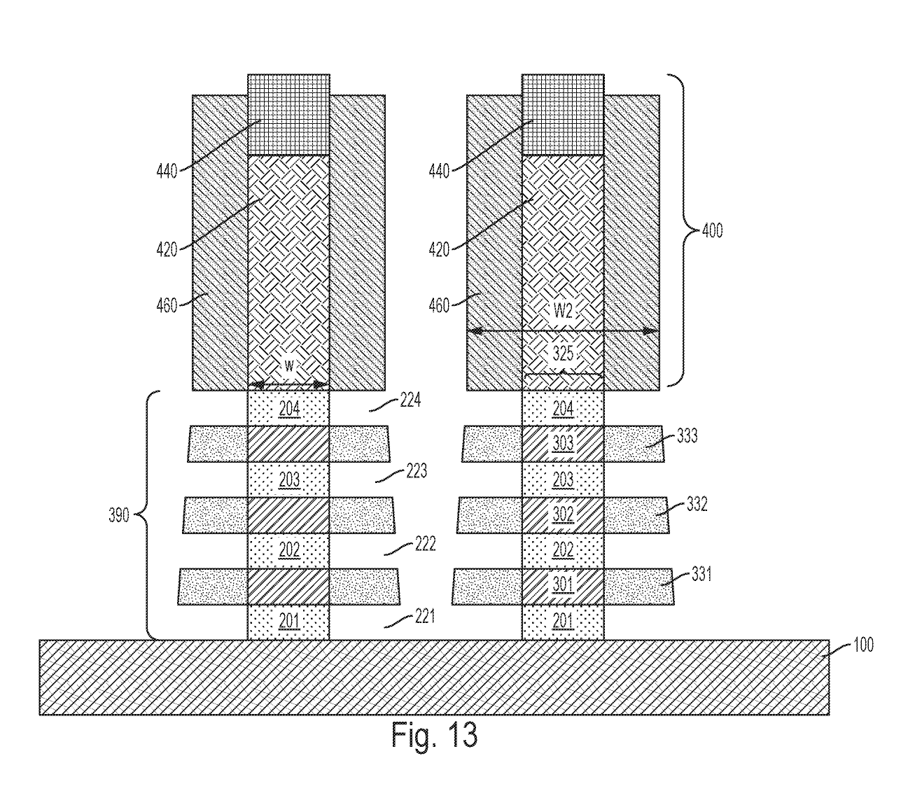

Referring to FIG. 13, the semiconductor epitaxial layers 301, 302, 303 are doped outside of channel regions 325 thereof to form extension regions 331, 332, 333. That is, the semiconductor epitaxial layers 301, 302, 303 are doped in regions laterally spaced from sacrificial gate layer 420 and underlying sidewall spacers 460. In certain embodiments, the extension regions are uniformly doped.

Doped regions may be formed by adding dopant atoms to an intrinsic semiconductor. This changes the electron and hole carrier concentrations of the intrinsic semiconductor at thermal equilibrium. A doped region may be p-type or n-type. As used herein, “p-type” refers to the addition of impurities to an intrinsic semiconductor that creates a deficiency of valence electrons. For silicon, example p-type dopants, i.e., impurities, include but are not limited to boron, aluminum, gallium, and indium. As used herein, “n-type” refers to the addition of impurities that contribute free electrons to an intrinsic semiconductor. For silicon, example n-type dopants, i.e., impurities, include but are not limited to, antimony, arsenic, and phosphorus. The dopant(s) may be introduced by ion implantation or plasma doping. Portions of the semiconductor epitaxial layers 301, 302, 303 underlying sacrificial gate layer 420, i.e., within channel regions 325, may remain undoped. Extension regions 331, 332, 333 provide a conductive path between the channels and later-formed source/drain junctions.

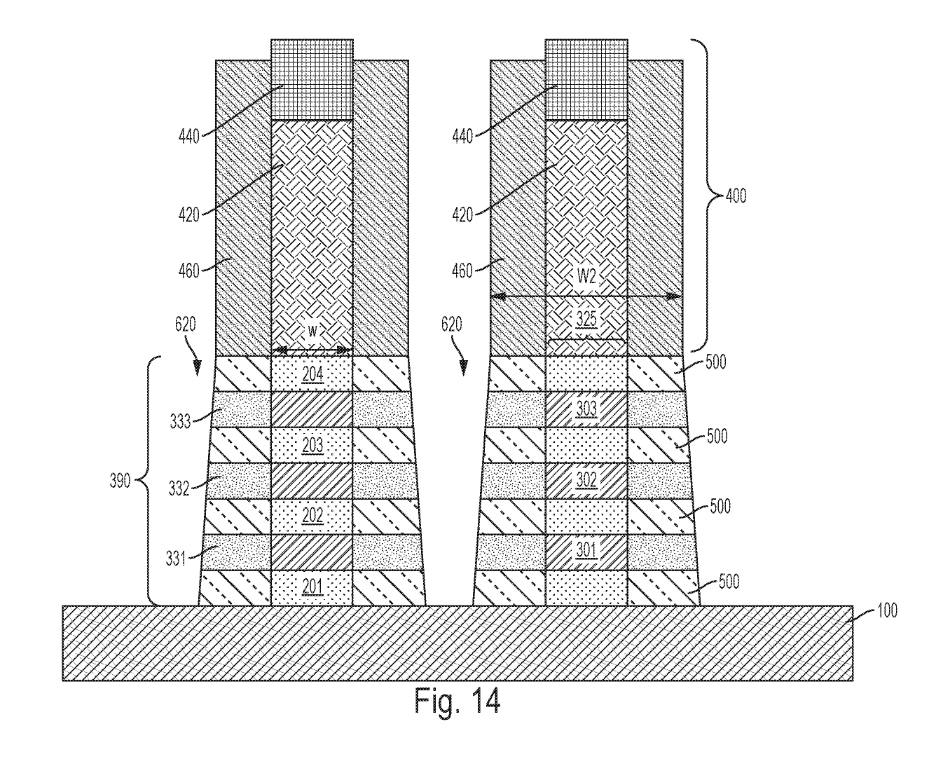

Turning to FIG. 14, following the formation of extension regions 331, 332, 333, inner spacers 500 are formed to re-fill the recessed regions 221, 222, 223, 224 created by the recess etch of the sacrificial layers 201, 202, 203, 204. Inner spacers 500 may be formed using a conformal ALD or CVD deposition process followed by an isotropic etch back. In connection with various embodiments, inner spacers 500 comprise a material that is etch selective to silicon germanium, such as silicon nitride, although inner spacers 500 may comprise other etch selective dielectric materials. As a result of the formation of the inner spacers 500, sidewalls surfaces of the extension regions 331, 332, 333 remain exposed, but the sacrificial layers 201, 202, 203, 204 are covered by the inner spacer material.

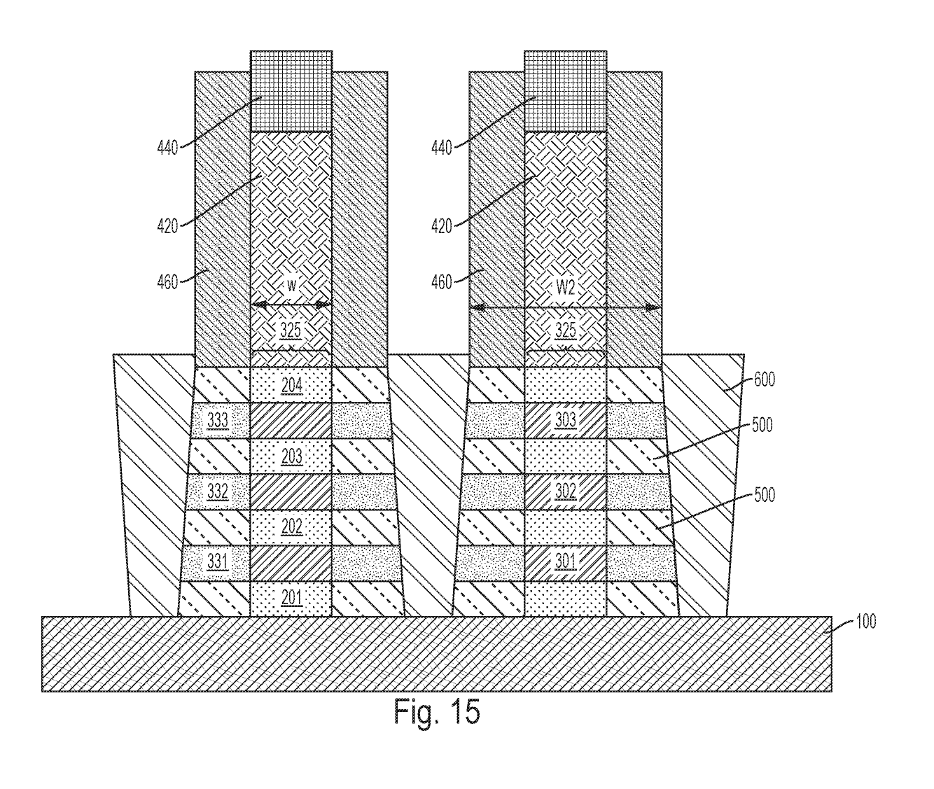

Thereafter, referring to FIG. 15, doped epitaxial source/drain junctions 600 are formed within source/drain recesses 620 by epitaxial growth from exposed portions of the semiconductor epitaxial layers 331, 332, 332. The epitaxial source/drain junctions 600 are electrically connected to semiconductor epitaxial layers 301, 302, 303 within the channel regions of the structure through the extension regions 331, 332, 333, but isolated from sacrificial layers 201, 202, 203, 204 by inner spacers 500

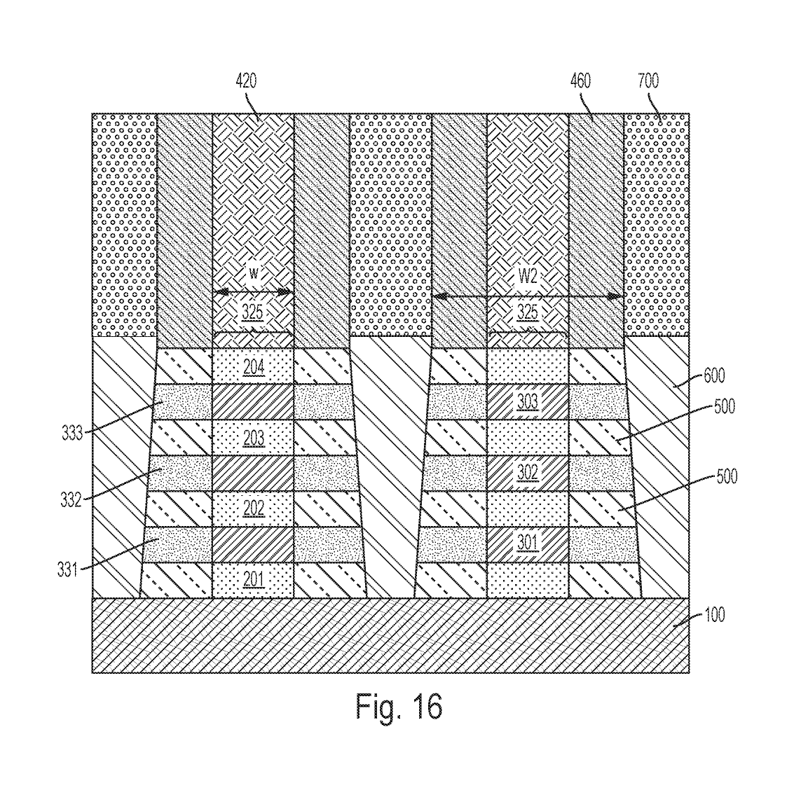

Referring to FIG. 16, an interlayer dielectric 700 is formed over the source/drain junctions 600 and between exposed sidewalls of the sidewall spacers 460. The ILD layer 700 may be formed using a CVD process and may comprise a low dielectric constant material. For example, the ILD layer 700 may comprise an oxide such as SiO₂, borophosphosilicate glass (BPSG), TEOS, undoped silicate glass (USG), fluorinated silicate glass (FSG), high-density plasma (HDP) oxide, or plasma-enhanced TEOS (PETEOS).

A CMP process may be used to remove the ILD overburden and planarize a top surface of the structure. “Planarization” refers to a material removal process that employs at least mechanical forces, such as frictional media, to produce a substantially two-dimensional surface. A planarization process may include chemical mechanical polishing (CMP) or grinding. Chemical mechanical polishing (CMP) is a material removal process that uses both chemical reactions and mechanical forces to remove material and planarize a surface. As seen in the illustrate embodiment of FIG. 16, the sacrificial gate layer 420 may serve as a CMP etch stop such that the CMP process removes the sacrificial gate cap 440.

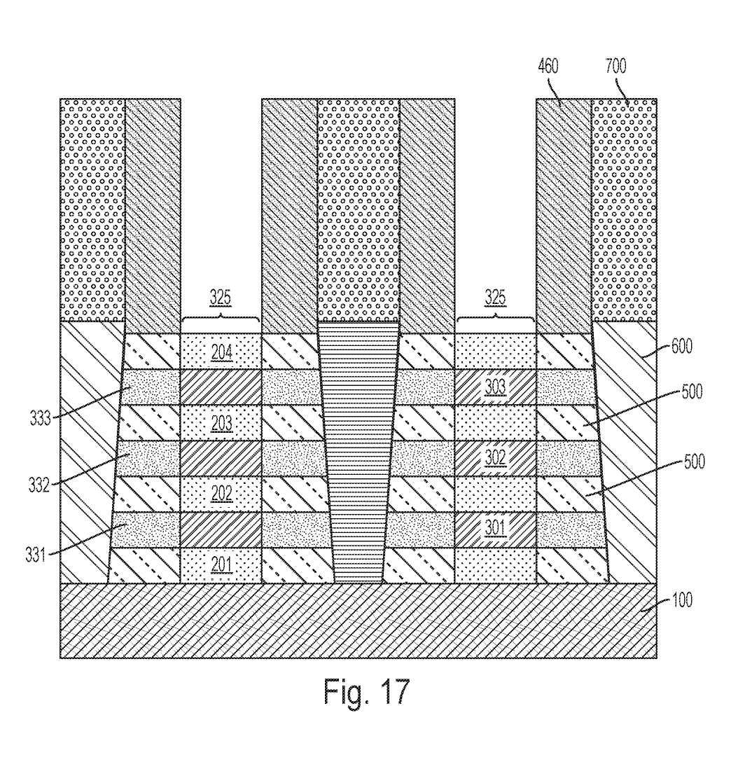

Thereafter, referring to FIG. 17, a selective etching step is used to remove the sacrificial gate layer 420. In embodiments where the sacrificial gate layer 420 comprises amorphous silicon, the sacrificial gate layer 420 can be etched and removed selectively with respect to silicon dioxide and silicon nitride using a wet etch chemistry comprising, for example, hot ammonia or TMAH.

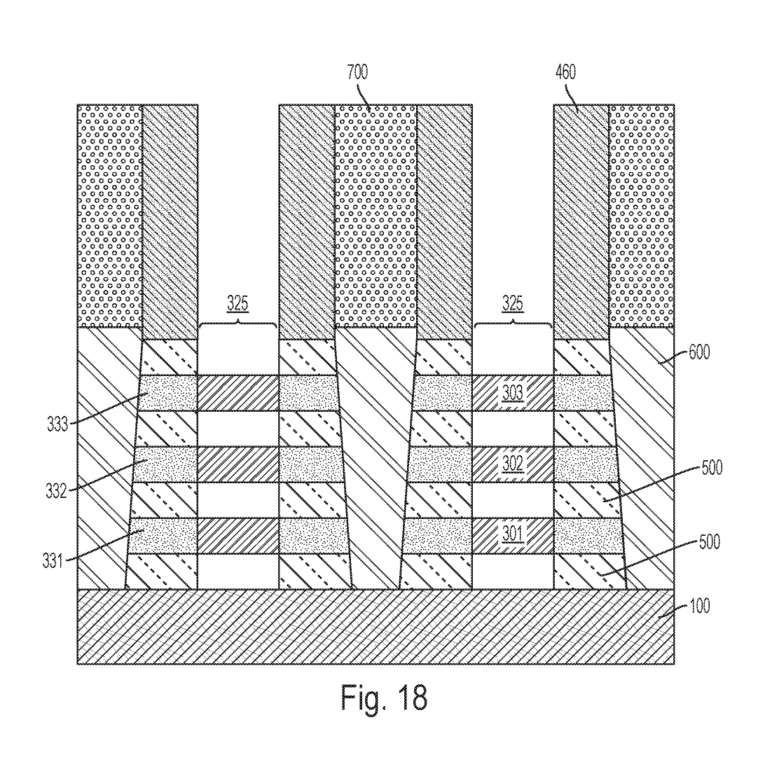

Referring to FIG. 18, subsequent to removal of the sacrificial gate layer 420, remaining portions of the sacrificial SiGe layers 201, 202, 203, 204 are removed selective to the semiconductor layers 301, 302, 303. During removal of the SiGe layers, inner spacers 500 and ILD layer 700 cooperate to protect the source/drain junctions 600, which may comprise SiGe.

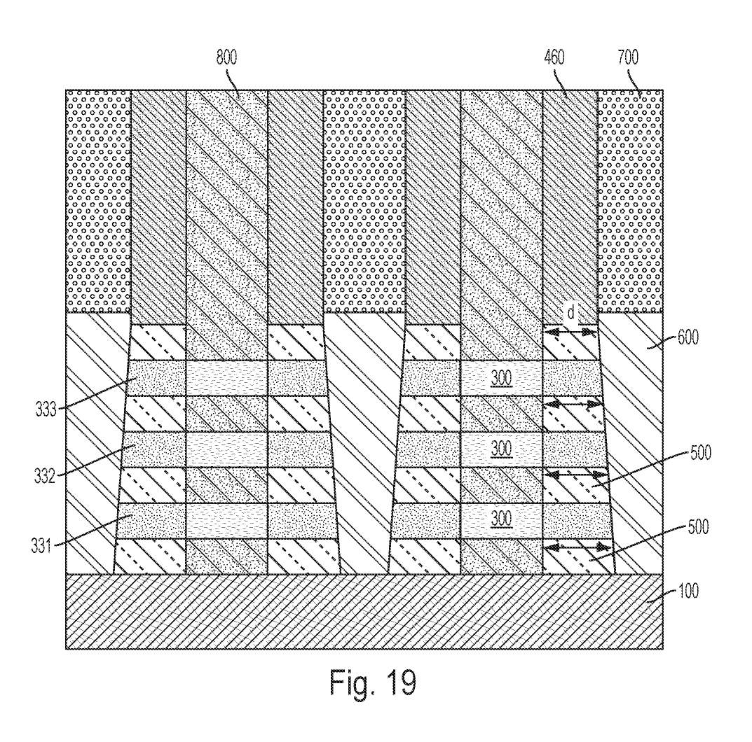

Referring to FIG. 19, after revealing nano-dimensional semiconductor layers 301, 302, 303, which each may have a substantially constant width, a functional gate structure 800 including gate dielectric and gate conductor layers (not separately shown) is deposited into the voids previously occupied by the sacrificial SiGe material to contact multiple surfaces of each nanostructure. Nano-dimensional semiconductor layers 301, 302 and 303 may be formed having a substantially constant width, i.e., within channel regions 325, by providing a successive layers, from bottom to top, having an overall germanium content that decreases from layer-to-layer, in addition to a bi-directional, intra-layer germanium gradient, as described above.

A semiconductor structure disclosed herein may include one or more transistors, with each device including a source, drain, channel and gate. Moreover, it will be appreciated that although the various methods described herein relate to exemplary gate all around PET structures, such methods are not limited to a particular device architecture and may be used in conjunction with any other type of device or structure now known or later developed.

The methods described herein may be used, for example, for the fabrication of integrated circuit (IC) chips. The resulting integrated circuit chips can be distributed by the fabricator in raw wafer form, i.e., as a single wafer that has multiple unpackaged chips, as a bare die, or in packaged form. In the latter case, the chip may be mounted in a single chip package such as a plastic carrier, with leads that are affixed to a motherboard or other higher level carrier, or in a multichip package such as a ceramic carrier that has either or both surface interconnections or buried interconnections. In any case, the chip may then be integrated with other chips, discrete circuit elements, and/or other signal processing devices as part of either an intermediate product, such as a motherboard, or an end product. The end product can be any product that includes integrated circuit chips, ranging from toys and to advanced computer products having a central processor, a display, and a keyboard or other input device.

As used herein, the singular forms “a,” “an” and “the” include plural referents unless the context clearly dictates otherwise. Thus, for example, reference to a “silicon nanosheet” includes examples having two or more such “nanosheets” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a nanosheet that comprises silicon include embodiments where a nanosheet consists essentially of silicon and embodiments where a nanosheet consists of silicon.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

1. A method of fabricating a device, comprising:
forming a stack of alternating layers of epitaxial silicon germanium and epitaxial silicon over a semiconductor substrate, wherein a germanium content within lower and upper regions of each said layer of epitaxial silicon germanium is greater than a germanium content within an intermediate region between said lower and upper regions;
forming a sacrificial gate structure over the stack, wherein the sacrificial gate structure has a length and a width less than the length;
forming sidewall spacers over sidewalls of the sacrificial gate structure; and
etching exposed portions of the stack using the sacrificial gate structure and the sidewall spacers as an etch mask to form a fin structure.

2. The method of claim 1, further comprising removing the epitaxial silicon germanium layers from under the sidewall spacers to form recessed regions.

3. The method of claim 2, further comprising forming dielectric inner spacers within the recessed regions.

4. The method of claim 1, further comprising removing portions of the epitaxial silicon germanium layers from under the sidewall spacers, wherein a distribution of the germanium content within each of the silicon germanium layers causes remaining portions of the silicon germanium layers to have a substantially constant width.

5. The method of claim 1, wherein sidewalls of the stack after etching the exposed portions are inclined at an angle (α) relative to a direction orthogonal to a major surface of the substrate, where 0≤α≤15°.

6. The method of claim 1, wherein a first layer of said layers of epitaxial silicon germanium is formed directly over the substrate.

7. The method of claim 1, wherein a topmost layer in the stack of alternating layers comprises epitaxial silicon germanium.

8. The method of claim 1, wherein the germanium content within the lower and upper regions of each said layer of epitaxial silicon germanium is 5 to 25 atomic percent greater than the germanium content within the intermediate region.

9. The method of claim 1, wherein the germanium content varies discontinuously within each said layer of epitaxial silicon germanium.

10. The method of claim 1, wherein the germanium content varies continuously within each said layer of epitaxial silicon germanium.

11. The method of claim 1, wherein the fin structure has a first width of 6 to 100 nm measured orthogonal to the width of the sacrificial gate structure and a second width of 25 to 65 nm measured parallel to the width of the sacrificial gate structure.

12. The method of claim 1, further comprising forming epitaxial source/drain regions laterally adjacent to the fin structure.

13. The method of claim 1, further comprising removing the sacrificial gate structure from over the fin structure to form an opening and removing the epitaxial silicon germanium layers beneath the opening selective to the epitaxial silicon layers, wherein exposed portions of the epitaxial silicon layers define channel regions of the device.

14. The method of claim 13, wherein the channel regions each have a substantially constant width.

15. A method of fabricating a device, comprising:
forming a stack of alternating layers of epitaxial silicon germanium and epitaxial silicon over a semiconductor substrate, wherein forming each layer of silicon germanium comprises forming a first sub-layer having a first germanium content, forming a second sub-layer over the first sub-layer having a second germanium content less than the first germanium content, and forming a third sub-layer over the second sub-layer having a third germanium content greater than the second germanium content;
forming a sacrificial gate structure over the stack of alternating layers;
forming sidewall spacers over sidewalls of the sacrificial gate structure;
etching the stack of alternating layers using the sacrificial gate structure and the sidewall spacers as an etch mask to form a fin structure; and
removing the silicon germanium layers from under the sidewall spacers to form recessed regions, wherein remaining portions of the silicon germanium layers each have a substantially constant width across the layer.

16. The method of claim 15, wherein each epitaxial layer of silicon is formed between an underlying layer of epitaxial silicon germanium and an overlying layer of epitaxial silicon germanium.

17. The method of claim 15, wherein the first germanium content is equal to the third germanium content.

18. The method of claim 15, wherein a thickness of the first sub-layer is equal to a thickness of the third sub-layer.
